(19) United States
(12) Patent Application Publication
(10) Pub. No.: US 2024/0339318 A1
(43) Pub. Date: Oct. 10, 2024

(54) SEGMENTED FORMATION OF GATE INTERFACE

(71) Applicant: Applied Materials, Inc., Santa Clara, CA (US)

(72) Inventors: Steven C. H. HUNG, Sunnyvale, CA (US); Theresa Kramer GUARINI, San Jose, CA (US); Johanes F. SWENBERG, Los Gatos, CA (US)

(21) Appl. No.: 18/595,374

(22) Filed: Mar. 4, 2024

Related U.S. Application Data
(60) Provisional application No. 63/458,331, filed on Apr. 10, 2023.

(51) Int. Cl. H01L 21/02; C23C 8/16; C23C 8/36; C23C 8/80; C23C 16/02; C23C 16/40; C23C 16/455; C23C 16/52; C23C 16/56; C23C 28/04

(52) U.S. Cl. CPC H01L 21/02332; C23C 8/16; C23C 8/36; C23C 8/80; C23C 16/0227; C23C 16/405; C23C 16/45527; C23C 16/52; C23C 16/56; C23C 28/042; H01L 21/02181; H01L 21/02205; H01L 21/0228; H01L 21/02301; H01L 21/0234

(57) ABSTRACT

A method of forming a semiconductor structure includes performing a first deposition process to deposit a first high-K dielectric layer on a surface of a substrate, performing an interface formation process to form an interfacial layer on the surface of the substrate, performing a second deposition process to deposit a second high-K dielectric layer on the interfacial layer, performing a plasma nitridation process to insert nitrogen atoms in the first high-K dielectric layer and the second high-K dielectric layer, and performing an anneal process to passivate chemical bonds in the first high-K dielectric layer and the second high-K dielectric layer.

### CROSS-REFERENCE TO RELATED APPLICATIONS

This application claims priority to U.S. Provisional Application Ser. No. 63/458,331 filed Apr. 10, 2023, which is herein incorporated by reference in its entirety.

### BACKGROUND

### Field

Embodiments described herein generally relate to semiconductor device fabrication, and more particularly, to systems and methods of forming a high quality high-K dielectric material layer in a semiconductor structure.

### Description of the Related Art

As metal-oxide-semiconductor field-effect transistors (MOSFETs) have decreased in size to achieve high device performance and low power consumption, the thickness of a traditional silicon dioxide (SiO₂) gate dielectric has to be decreased in order to enhance the transistor speed, which unfortunately also causes the increase in leakage current. As a result, replacing the silicon dioxide gate dielectric with a high-κ dielectric material has been inevitable to achieve further scaling without hindering leakage performance. Among various high-K dielectric materials, hafnium oxide (HfO₂) has been applied since the 45 nm MOSFET technology node due to its high dielectric constant and superior thermal stability on a silicon substrate. However, for further scaling of equivalent oxide thickness (EOT) for the 32 nm MOSFET technology node and beyond, simply decreasing the thickness of a high-κ dielectric material layer is problematic due to an increase of overall leakage current through the SiO₂ and high-K dielectric bi-layer.

Thus, there is a need for systems and methods that can be used to form thin (e.g., EOT less than 1 nm) high-K dielectric material layers having chemical structures that can be controlled to ensure desired structural and electrical properties.

### SUMMARY

Embodiments of the present disclosure provide a method of forming a semiconductor structure. The method includes performing a first deposition process to deposit a first high-K dielectric layer on a surface of a substrate, performing an interface formation process to form an interfacial layer on the surface of the substrate, performing a second deposition process to deposit a second high-K dielectric layer on the interfacial layer, performing a plasma nitridation process to insert nitrogen atoms in the first high-K dielectric layer and the second high-K dielectric layer, and performing an anneal process to passivate chemical bonds in the first high-K dielectric layer and the second high-K dielectric layer.

Embodiments of the present disclosure also provide a method of forming a semiconductor structure. The method includes performing a first deposition process to deposit a first high-K dielectric layer on a surface of a substrate, performing an interface formation process to form an interfacial layer on the surface of the substrate, and performing a second deposition process to deposit a second high-K dielectric layer on the interfacial layer.

Embodiments of the present disclosure further provide a processing system. The processing system includes a first processing chamber, a second processing chamber, a third processing chamber, a fourth processing chamber, a fifth processing chamber, a sixth processing chamber, and a system controller configured to perform a first deposition process to deposit a first high-K dielectric layer on a surface of a substrate in the first processing chamber, performing an interface formation process to form an interfacial layer on the surface of the substrate in the second processing chamber, performing a second deposition process to deposit a second high-K dielectric layer on the interfacial layer in the third processing chamber, performing a plasma nitridation process to insert nitrogen atoms in the first high-K dielectric layer and the second high-K dielectric layer in the fourth processing chamber, and performing an anneal process to passivate chemical bonds in the first high-K dielectric layer and the second high-K dielectric layer in the fifth processing chamber, wherein the substrate is transferred among the first, second, third, fourth, and fifth processing chambers without breaking vacuum environment in the processing system.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic top-view diagram of an example multi-chamber processing system according to one embodiment.

FIG. 2 is a process flow diagram of a method of forming a semiconductor structure according to one embodiment.

FIGS. 3A, 3B, and 3C are schematic views of a semiconductor structure according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

As gate structures scale to smaller dimensions, new material structures are being sought to provide improvements. The use of high-κ dielectric materials increases the dielectric constant of the gate structure over conventional gate structures that utilize materials such as silicon oxide. However, similar to silicon oxide, as the thickness of a gate structure is reduced, leakage currents increase. For example, gate leakage increases as the effective oxide thickness decreases. Hence, the inverse relationship between gate leakage and effective oxide thickness may form a limit on the performance of the transistor and the device produced.

High-κ dielectric materials may provide greater channel mobility over silicon oxide at similar thicknesses. As the industry continues to seek lower effective oxide thicknesses without increased gate leakage, efforts to maximize a dielectric constant (also referred to as “κ-value”) of known high-κ materials are reaching limits due to morphological characteristics. Conventional technologies have struggled to overcome natural characteristics of high-κ materials, which may set an upper limit in the κ-value, and subsequent device remodeling in attempts to incorporate new films.

The embodiments described herein provide systems and methods for improving the characteristics of high-κ dielectric materials. By producing high-κ dielectric materials in two segments, formation of grains within the high-κ dielectric materials during a thermal oxidation process can be suppressed, leading to improved device performance. Further, the high-κ dielectric materials in the two segments can be different, which may result in a higher overall dielectric constant.

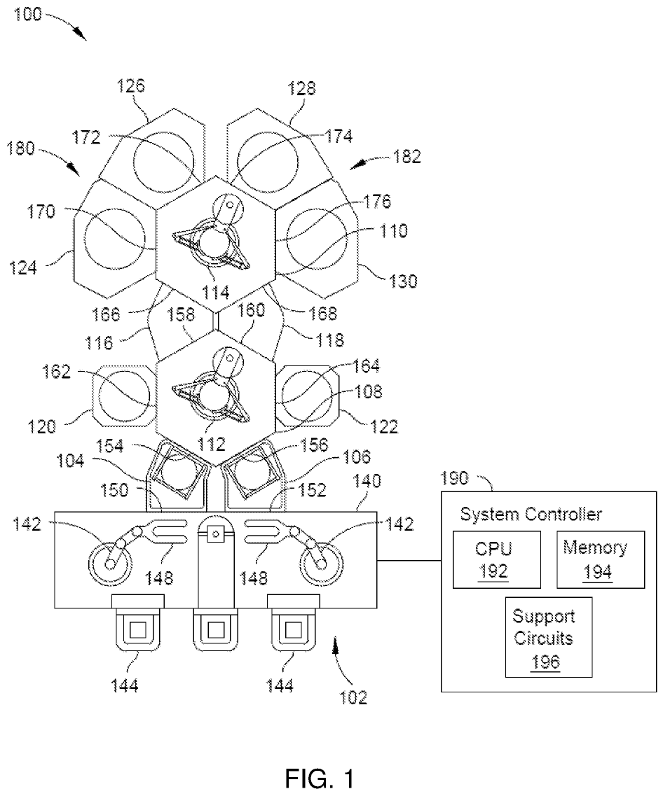

FIG. 1 is a schematic top-view diagram of an example of a multi-chamber processing system 100 according to some examples of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, wafers in the processing system 100 can be processed in and transferred between the various chambers without exposing the wafers to an ambient environment exterior to the processing system 100 (e.g., an atmospheric ambient environment such as may be present in a fab). For example, the wafers can be processed in and transferred between the various chambers in a low pressure (e.g., less than or equal to about 300 Torr) or vacuum environment without breaking the low pressure or vacuum environment between various processes performed on the wafers in the processing system 100. Accordingly, the processing system 100 may provide for an integrated solution for some processing of wafers.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 140 and factory interface robots 142 to facilitate transfer of wafers. The docking station 140 is configured to accept one or more front opening unified pods (FOUPs) 144. In some examples, each factory interface robot 142 generally comprises a blade 148 disposed on one end of the respective factory interface robot 142 configured to transfer the wafers from the factory interface 102 to the load lock chambers 104, 106.

The load lock chambers 104, 106 have respective ports 150, 152 coupled to the factory interface 102 and respective ports 154, 156 coupled to the transfer chamber 108. The transfer chamber 108 further has respective ports 158, 160 coupled to the holding chambers 116, 118 and respective ports 162, 164 coupled to processing chambers 120, 122. Similarly, the transfer chamber 110 has respective ports 166, 168 coupled to the holding chambers 116, 118 and respective ports 170, 172, 174, 176 coupled to processing chambers 124, 126, 128, 130. The ports 154, 156, 158, 160, 162, 164, 166, 168, 170, 172, 174, 176 can be, for example, slit valve openings with slit valves for passing wafers therethrough by the transfer robots 112, 114 and for providing a seal between respective chambers to prevent a gas from passing between the respective chambers. Generally, any port is open for transferring a wafer therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 142 transfers a wafer from a FOUP 144 through a port 150 or 152 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the wafer between, for example, the atmospheric environment of the factory interface 102 and the low pressure or vacuum environment of the transfer chamber 108.

With the wafer in the load lock chamber 104 or 106 that has been pumped down, the transfer robot 112 transfers the wafer from the load lock chamber 104 or 106 into the transfer chamber 108 through the port 154 or 156. The transfer robot 112 is then capable of transferring the wafer to and/or between any of the processing chambers 120, 122 through the respective ports 162, 164 for processing and the holding chambers 116, 118 through the respective ports 158, 160 for holding to await further transfer. Similarly, the transfer robot 114 is capable of accessing the wafer in the holding chamber 116 or 118 through the port 166 or 168 and is capable of transferring the wafer to and/or between any of the processing chambers 124, 126, 128, 130 through the respective ports 170, 172, 174, 176 for processing and the holding chambers 116, 118 through the respective ports 166, 168 for holding to await further transfer. The transfer and holding of the wafer within and among the various chambers can be in the low pressure or vacuum environment provided by the gas and pressure control system.

The processing chambers 120, 122, 124, 126, 128, 130 can be any appropriate chamber for processing a wafer. In some examples, the processing chamber 122 can be capable of performing a cleaning process, the processing chamber 120 can be capable of performing an etch process, the processing chambers 124 can be capable of performing respective deposition processes, the processing chamber 126 can be a rapid thermal oxidation (RTO) chamber, the processing chamber 128 can be a decoupled plasma nitridation (DPN) chamber, and the processing chamber 130 can be a rapid thermal processing (RTP) chamber. The processing chamber 122 may be a SiCoNi™ Preclean chamber available from Applied Materials of Santa Clara, Calif. The processing chamber 120 may be a Selectra™ Etch chamber available from Applied Materials of Santa Clara, Calif. The processing chamber 124 may be a Centura® Epi chamber, Volta® CVD/ALD chamber, or EnCoRe® PVD chamber available from Applied Materials of Santa Clara, Calif. The processing chamber 128 may be Centura® DPN chamber, available from Applied Materials of Santa Clara, Calif. The processing chamber 130 may be RadOx™ chamber, available from Applied Materials of Santa Clara, Calif.

A system controller 190 is coupled to the processing system 100 for controlling the processing system 100 or components thereof. For example, the system controller 190 may control the operation of the processing system 100 using a direct control of the chambers 104, 106, 108, 116, 118, 110, 120, 122, 124, 126, 128, 130 of the processing system 100 or by controlling controllers associated with the chambers 104, 106, 108, 116, 118, 110, 120, 122, 124, 126, 128, 130. In operation, the system controller 190 enables data collection and feedback from the respective chambers to coordinate performance of the processing system 100.

The system controller 190 generally includes a central processing unit (CPU) 192, memory 194, and support circuits 196. The CPU 192 may be one of any form of a general purpose processor that can be used in an industrial setting. The memory 194, or non-transitory computer-readable medium, is accessible by the CPU 192 and may be one or more of memory such as random access memory (RAM), read only memory (ROM), floppy disk, hard disk, or any other form of digital storage, local or remote. The support circuits 196 are coupled to the CPU 192 and may comprise cache, clock circuits, input/output subsystems, power supplies, and the like. The various methods disclosed herein may generally be implemented under the control of the CPU 192 by the CPU 192 executing computer instruction code stored in the memory 194 (or in memory of a particular process chamber) as, for example, a software routine. When the computer instruction code is executed by the CPU 192, the CPU 192 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

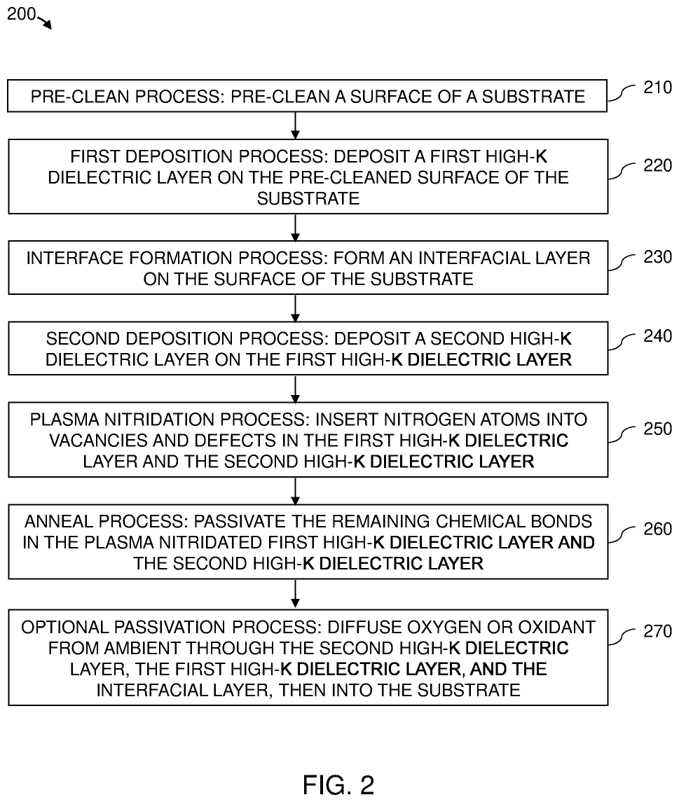

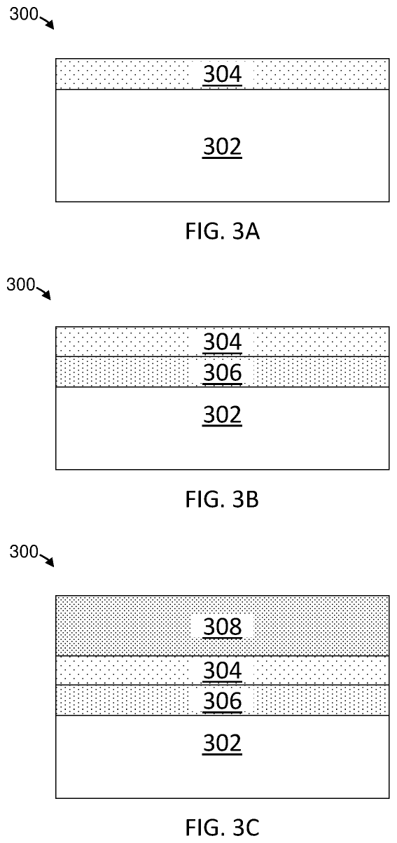

FIG. 2 is a process flow diagram of a method 200 of forming a semiconductor structure 300 according to one or more implementations of the present disclosure. FIGS. 3A, 3B, and 3C are cross-sectional views of a portion of the semiconductor structure 300 corresponding to various states of the method 200. It should be understood that FIGS. 3A, 3B, and 3C illustrate only partial schematic views of the semiconductor structure 300, and the semiconductor structure 300 may contain any number of transistor sections and additional materials having aspects as illustrated in the figures. It should also be noted although the method steps illustrated in FIG. 2 are described sequentially, other process sequences that include one or more method steps that have been omitted and/or added, and/or has been rearranged in another desirable order, fall within the scope of the embodiments of the disclosure provided herein.

The method 200 begins with a pre-clean process in block 210 to pre-clean a surface of the substrate 302. The pre-clean process may include etching the surface of the substrate 302 by a wet etch process using an etch solution, such as a Standard Clean 1 (SC1) etch solution including NH₄OH (ammonium hydroxide), H₂O₂ (hydrogen peroxide), and H₂O (water), or a dry etch process, for example, a SiConi™ remote plasma assisted dry etch process, in which the surface of the substrate 302 is exposed to N₂, NF₃, and NH₃ plasma by-products. The pre-clean process may be performed in an appropriate pre-clean chamber.

In block 220, subsequent to the pre-clean process, a first deposition process is performed to deposit a first high-κ dielectric layer 304 on the pre-cleaned surface of the substrate 302, as shown in FIG. 3A. The first high-κ dielectric layer 304 may be formed of first high-κ dielectric material, such as hafnium dioxide (HfO₂), zirconium dioxide (ZrO₂), ytterbium oxide (Y₂O₃), or aluminum oxide (Al₂O₃). The first high-κ dielectric layer 304 has a minimum thickness as a continuous layer (e.g., a monolayer of the first high-κ dielectric material) on the pre-cleaned surface of the substrate 302, between about 3 Å and about 10 Å, for example, about 5 Å. At this thickness, no grains are formed within the first high-κ dielectric layer 304 during the subsequent thermal oxidation process in block 230. The deposition process may include an atomic layer deposition (ALD) blanket deposition process, in which a metal-containing precursor and an oxygen-containing precursor are alternately delivered to the exposed surface of the semiconductor structure 300. In some embodiments, the metal-containing precursor is purged prior to delivering the oxygen-containing precursor. The metal may be a transition metal, such as hafnium (Hf), zirconium (Zr), or titanium (Ti), a rare-earth metal, such as lanthanum (La), ytterbium (Yb), or yttrium (Y), an alkaline earth metal, such as strontium (Sr), or other metal such as aluminum (Al). For the oxidant, any oxygen-containing precursor may be used that may react with the metal. For example, the oxygen-containing precursor may be or include water, ozone, hydrogen peroxide, diatomic oxygen, a hydroxyl-containing precursor or alcohol, nitrogen-and-oxygen-containing precursors, plasma-enhanced oxygen including locally or remotely enhanced oxygen, or any other material including oxygen that may be incorporated with the metal to produce a layer of an oxide of the metal over the substrate 302. In one example, the metal-containing precursor is hafnium tetrachloride (HfCl₄) and the oxidant is water (H₂O) to form a hafnium dioxide (HfO₂) layer. The ALD process may be performed at a temperature of between about 200° C. and about 400° C., for example, about 270° C. The first high-κ dielectric layer 304, as deposited, may be amorphous. The first deposition process may be performed in a processing chamber, such as the processing chamber 124 or 126 shown in FIG. 1. In some embodiments, the first deposition process may include a chemical vapor deposition (CVD) process or a physical vapor deposition process (PVD) process.

In block 230, subsequent to the first deposition process, an interface formation process is performed to form an interfacial layer 306 on the surface of the substrate 302, as shown in FIG. 3B. The interface formation process may include a suitable thermal oxidation process of the surface of the substrate through the first high-K dielectric layer 304, such as an enhanced in-situ steam generation (eISSG) process utilizing nitrous oxide (N₂O) gas. The interfacial layer 306 formed in block 230 is a thin amorphous silicon oxide (SiO₂) layer, having a thickness of between about 3 Å and about 10 Å, for example, about 5 Å, corresponding to one or more monolayers of silicon oxide. In some embodiments, the interfacial layer 306 may be formed by an in-situ steam generation (ISSG) process utilizing H₂ and O₂ gases, or a rapid thermal oxidation (RTO) process utilizing O₂ gas. The interfacial layer 306 may improve quality (e.g., such as interface state density, accumulation capacitance, frequency dispersion, and leakage current) of the interface between the substrate 302 and the high-κ dielectric material layer. The interface formation process may be performed in a processing chamber, such as the processing chamber 128 shown in FIG. 1.

In block 240, subsequent to the interface formation process, a second deposition process is performed to deposit a second high-κ dielectric layer 308 on the first high-κ dielectric layer 304, as shown in FIG. 3C. The second high-κ dielectric layer 308 may be formed of second high-κ dielectric material, such as hafnium dioxide (HfO₂), zirconium dioxide (ZrO₂), ytterbium oxide (Y₂O₃), or aluminum oxide (Al₂O₃). The second high-κ dielectric material may be the same as or different from the first high-κ dielectric material. For example, the second high-κ dielectric material may be hafnium dioxide (HfO₂) doped with a transition metal, such as zirconium (Zr) or titanium (Ti), or a rare-earth metal, such as lanthanum (La), to increase κ-value of the second high-κ dielectric layer 308, for example, by about 25%. The second high-κ dielectric layer 308 has a thickness of between about 10 Å and about 25 Å. The second deposition process in block 240 is generally the same as the first deposition process in block 220. The second high-κ dielectric layer 308, as deposited, may be amorphous.

In block 250, subsequent to the second deposition process, a plasma nitridation process is performed to insert nitrogen atoms into vacancies and defects in the first high-κ dielectric layer 304 and the second high-κ dielectric layer 308. The plasma nitridation process may be a decoupled plasma nitridation (DPN) process performed in a DPN chamber such as the processing chamber 130 shown in FIG. 1. The plasma nitridation process exposes the first high-κ dielectric layer 304 and the second high-κ dielectric layer 308 to nitrogen plasma, which may allow nitrogen radicals or nitrogen atoms to be incorporated within the first high-κ dielectric layer 304 and the second high-κ dielectric layer 308, throughout the thickness of the first high-κ dielectric layer 304 and the second high-κ dielectric layer 308. Gases that may be used in the plasma process include nitrogen containing gas, such as nitrogen (N₂), ammonia (NH₃), or mixtures thereof. In one example, the nitrogen gas is ammonia (NH₃) mixed with about 3% to about 8% of nitrogen (N₂). The plasma nitridation process may not change a thickness of the first high-κ dielectric layer 304 and the second high-κ dielectric layer 308 as a result of the nitrogen incorporation to vacancies and defects in the first high-κ dielectric layer 304 and the second high-κ dielectric layer 308. The plasma nitridation process may increase the overall κ-value of the first high-K dielectric layer 304 and the second high-κ dielectric layer 308, for example, by about 25%.

The nitridation process may be performed for between about 10 seconds and about 300 seconds, at a temperature of between about 0° C. and about 500° C.

In block 260, subsequent to the plasma nitridation process, an anneal process is performed to passivate the remaining chemical bonds in the plasma nitridated first high-κ dielectric layer 304 and the second high-κ dielectric layer 308. The anneal process may include a spike thermal anneal process in a nitrogen (N₂) and argon (Ar) ambient, performed in a rapid thermal processing (RTP) chamber, such as the processing chamber 130 shown in FIG. 1. The anneal process may passivate metastable nitrogen bonds formed in the plasma nitridation process in block 240 and crystallization of the amorphous the first high-κ dielectric layer 304 and the second high-κ dielectric layer 308 may occur.

The spike thermal anneal process may be performed for between about 1 second and about 30 seconds, at a temperature of between about 700° C. and about 850° C., and at a pressure of between about 10 Torr and 740 Torr.

In block 270, subsequent to the anneal process, an optional passivation process is performed to diffuse oxygen or oxidant from ambient through the second high-κ dielectric layer 308, the first high-κ dielectric layer 304, and the interfacial layer 306, then into the substrate 302, forming fresh silicon dioxide (SiO₂) monolayers added to the interfacial layer 306 formed in block 230. The passivation process may include a thermal anneal process in an oxygen (O₂) ambient, performed in a rapid thermal processing (RTP) chamber, such the processing chamber 130 shown in FIG. 1. The passivation process may improve reliability of a device formed on the substrate 302, for example, extending the device lifetime of a p-type transistor.

The passivation process may be performed for between about 1 second and about 60 seconds, at a lower temperature of between about 500° C. and about 800° C., and at a low pressure of between about 1 Torr and 50 Torr.

The first deposition process in block 220, the interface formation process in block 230, the second deposition process in block 240, the plasma nitridation process in block 250, the anneal process in block 260, and the optional passivation process in block 270 may be performed without breaking vacuum environment in a multi-chamber processing system, such as the multi-chamber processing system 100 shown in FIG. 1.

In the embodiments described herein, the systems and the methods of forming high-quality thin high-κ dielectric material layers are provided. A high-κ dielectric material layer is produced in two segments, in one of which a thin high-κ dielectric material layer is deposited prior to a thermal oxidation process and in the other of which a thicker high-κ dielectric material layer is deposited. Thus, formation of grains within the overall high-κ dielectric layer during the thermal oxidation process can be suppressed, leading to improved device performance.

While the foregoing is directed to embodiments of the present disclosure, other and further embodiments of the disclosure may be devised without departing from the basic scope thereof, and the scope thereof is determined by the claims that follow.

1. A method of forming a semiconductor structure, the method comprising:
performing a first deposition process to deposit a first high-κ dielectric layer on a surface of a substrate;
performing an interface formation process to form an interfacial layer on the surface of the substrate;
performing a second deposition process to deposit a second high-κ dielectric layer on the interfacial layer;
performing a plasma nitridation process to insert nitrogen atoms in the first high-κ dielectric layer and the second high-κ dielectric layer; and
performing an anneal process to passivate chemical bonds in the first high-κ dielectric layer and the second high-κ dielectric layer.

2. The method of claim 1, wherein the first deposition process, the interface formation process, the second deposition process, the plasma nitridation process, and the anneal process are performed in a processing system without breaking vacuum.

3. The method of claim 1, further comprising:
prior to the first deposition process, pre-cleaning the surface of the substrate; and
subsequent to the anneal process, performing a passivation process to diffuse oxygen or oxidant from ambient through the second high-κ dielectric layer, the first high-κ dielectric layer, and the interfacial layer into the substrate.

4. The method of claim 1, wherein
the first high-κ dielectric layer comprises hafnium oxide (HfO₂) and has a thickness of between 3 Å and 10 Å, and
the second high-κ dielectric layer comprises hafnium oxide (HfO₂) and has a thickness of between 10 Å and 25 Å.

5. The method of claim 1, wherein the first deposition process and the second deposition process each comprise an atomic layer deposition (ALD) process, in which hafnium tetrachloride (HfCl₄) and water are alternately delivered to the substrate.

6. The method of claim 1, wherein
the interfacial layer comprises silicon oxide (SiO₂), and
the interface formation process comprises thermally oxidizing the substrate through the first high-κ dielectric layer utilizing nitrous oxide (N₂O) gas.

7. The method of claim 1, wherein the plasma nitridation process comprises exposing the first high-κ dielectric layer and the second high-κ dielectric layer to nitrogen plasma using a mixture of nitrogen (N₂) and ammonia (NH₃) gas.

8. The method of claim 1, wherein the anneal process comprises spike annealing the first high-κ dielectric layer and the second high-κ dielectric layer in a nitrogen (N₂) and argon (Ar) ambient at a temperature of between of between 700° C. and 850° C.

9. A method of forming a semiconductor structure, the method comprising:
performing a first deposition process to deposit a first high-κ dielectric layer on a surface of a substrate;
performing an interface formation process to form an interfacial layer on the surface of the substrate; and
performing a second deposition process to deposit a second high-k dielectric layer on the interfacial layer.

10. The method of claim 9, wherein the first deposition process, the interface formation process, and the second deposition process are performed in a processing system without breaking vacuum.

11. The method of claim 9, wherein
the first high-κ dielectric layer comprises hafnium oxide (HfO₂) and has a thickness of between 3 Å and 10 Å, and
the second high-κ dielectric layer comprises hafnium oxide (HfO₂) and has a thickness of between 10 Å and 25 Å.

12. The method of claim 9, wherein the first deposition process and the second deposition process each comprise an atomic layer deposition (ALD) process, in which hafnium tetrachloride (HfCl₄) and water are alternately delivered to the substrate.

13. The method of claim 9, wherein
the interfacial layer comprises silicon oxide (SiO₂), and
the interface formation process comprises thermally oxidizing the substrate through the first high-κ dielectric layer utilizing nitrous oxide (N₂O) gas.

14. A processing system, comprising:
a first processing chamber;
a second processing chamber;
a third processing chamber;
a fourth processing chamber;
a fifth processing chamber; and
a system controller configured to:
perform a first deposition process to deposit a first high-κ dielectric layer on a surface of a substrate in the first processing chamber;
performing an interface formation process to form an interfacial layer on the surface of the substrate in the second processing chamber;
performing a second deposition process to deposit a second high-κ dielectric layer on the interfacial layer in the third processing chamber;
performing a plasma nitridation process to insert nitrogen atoms in the first high-κ dielectric layer and the second high-κ dielectric layer in the fourth processing chamber; and
performing an anneal process to passivate chemical bonds in the first high-κ dielectric layer and the second high-κ dielectric layer in the fifth processing chamber,
wherein the substrate is transferred among the first, second, third, fourth, and fifth processing chambers without breaking vacuum environment in the processing system.

15. The processing system of claim 14, further comprising:
a seventh processing chamber; and
an eighth processing chamber, wherein
the system controller is further configured to:
prior to the first deposition process, pre-clean the surface of the substrate in the seventh processing chamber; and
subsequent to the anneal process, perform a passivation process, in the eighth processing chamber, to diffuse oxygen or oxidant from ambient through the second high-κ dielectric layer, the first high-κ dielectric layer, and the interfacial layer into the substrate.

16. The processing system of claim 14, wherein
the first high-κ dielectric layer comprises hafnium oxide (HfO₂) and has a thickness of between 3 Å and 10 Å, and
the second high-κ dielectric layer comprises hafnium oxide (HfO₂) and has a thickness of between 10 Å and 25 Å.

17. The processing system of claim 14, wherein the first deposition process and the second deposition process each comprise an atomic layer deposition (ALD) process, in which hafnium tetrachloride (HfCl₄) and water are alternately delivered to the substrate.

18. The processing system of claim 14, wherein
the interfacial layer comprises silicon oxide (SiO₂), and
the interface formation process comprises thermally oxidizing the substrate through the first high-κ dielectric layer utilizing nitrous oxide (N₂O) gas.

19. The processing system of claim 14, wherein the plasma nitridation process comprises exposing the first high-κ dielectric layer and the second high-κ dielectric layer to nitrogen plasma using a mixture of nitrogen (N₂) and ammonia (NH₃) gas.

20. The processing system of claim 14, wherein the anneal process comprises spike annealing the first high-κ dielectric layer and the second high-κ dielectric layer in a nitrogen (N₂) and argon (Ar) ambient at a temperature of between of between 700° C. and 850° C.
